(19) United States
(12) Patent Application Publication
(10) Pub. No.: US 2009/0072271 A1
(43) Pub. Date: Mar. 19, 2009

(54) EPITAXIAL GROWTH OF THIN SMOOTH GERMANIUM (Ge) ON SILICON (Si) UTILIZING AN INTERFACIAL SILICON GERMANIUM (SiGe) PULSE GROWTH METHOD

(76) Inventors: Leonardo Gomez, Cambridge, MA (US); Meekyung Kim, Cambridge, MA (US); Judy L. Hoyt, Newton, MA (US)

Correspondence Address: Attn: Matthew E. Connors;Gauthier & Connors LLP, 225 Franklin Street, Suite 3300, Boston, MA, 02110, US

(21) Appl. No.: 12/212,918

(22) Filed: Sep. 18, 2008

Related U.S. Application Data
(60) Provisional application No. 60/973,226, filed on Sep. 18, 2007.

(51) Int. Cl. H01L 29/165; H01L 21/205

(52) U.S. Cl. 257/190; 438/478; 257/E21.103; 257/E29.085

(57) ABSTRACT

Disclosed is a method of growing thin and smooth germanium (Ge) on a strained or relaxed silicon (Si) layer comprising the steps of: (a) treating surface of the strained or relaxed Si layer to gaseous precursors of both Si (e.g., silane) and Ge (e.g., germane) for a predetermined short time duration Δt, where 1≦Δt≦30 seconds; and (b) depositing a thin Ge film on top of said treated Si layer, wherein said treatment step of (a) reduces growth time and surface roughness of the thin Ge film (e.g., sub-5 nm or sub-20 nm thick) deposited on the Si layer. The treatment step (a) can be conducted at a steady predetermined temperature T, where 450≦T≦900° C. The predetermined short time duration Δt can be chosen such that less than 10 A of SiGe is deposited.

### PRIORITY INFORMATION

This application claims priority from provisional application 60/973,226, filed Sep. 18, 2007 entitled, “Epitaxial Growth of Thin Smooth Germanium (Ge) on Silicon (Si) Utilizing an Interfacial Silicon Germanium (SiGe) Pulse Growth Method”, which is incorporated herein by reference in its entirety.

### BACKGROUND OF THE INVENTION

1. Field of Invention

The present invention relates generally to the field of thin films. More specifically, the present invention is related to the epitaxial growth of thin and smooth Germanium (Ge) on Silicon (Si) utilizing an interfacial Silicon Germanium (SiGe) pulse growth method.

2. Discussion of Prior Art

The paper to Lee et al. entitled, “Strained Ge channel p-type metal-oxide-semiconductor field-effect transistors grown in Si₁₋ₓGeₓ/Si virtual substrates” teaches a method for growing Germanium (Ge) on thick Silicon Germanium (SiGe). Specifically, Lee et al. disclose a Ge MOSFET structure having a Ge layer formed on top of a thick relaxed Si0.3Ge0.7 layer.

The U.S. patent to Brabant et al. (U.S. Pat. No. 7,238,595) provides for epitaxial semiconductor deposition methods and structures. According to Brabant et al., the Si surface is contacted with surface active compounds during a temperature ramp-down step in an epitaxial reactor, prior to growth of a high-Ge-content SiGe layer, for the purpose of improving the SiGe layer epitaxial layer quality. The Ge films produced as per Brabant et al.'s method have a thickness between 500 A and 2 μm. Brabant et al. do not teach or suggest a method for producing epitaxial structures with very thin layers of strained Si and Strained Ge in the final structure. Brabant et al's method, by contrast, teaches that uncontrolled growth may take place during temperature ramps.

Whatever the precise merits, features, and advantages of the above cited references, none of them achieves or fulfills the purposes of the present invention.

### SUMMARY OF THE INVENTION

The present invention provides for a method of growing thin and smooth germanium (Ge) on a strained silicon (Si) layer comprising the steps of: (a) treating surface of the strained Si layer to gaseous precursors of both Si (e.g., silane) and Ge (e.g., germane) for a predetermined short time duration Δt, where 1≦Δt≦30 seconds; and (b) depositing a thin Ge film on top of said treated Si layer, wherein said treatment step of (a) reduces growth time and surface roughness of the thin Ge film (e.g., sub-5 nm or sub-20 nm thick) deposited on the Si layer. In one embodiment, the treatment step (a) is conducted at a steady predetermined temperature T, where 450≦T≦900° C. In one embodiment, the predetermined short time duration Δt is chosen such that less than 10 A of SiGe is deposited.

The present invention provides for a method of growing thin and smooth germanium (Ge) on a relaxed silicon (Si) layer comprising the steps of: (a) treating surface of the relaxed Si layer to gaseous precursors of both Si (e.g., silane) and Ge (e.g., germane) for a predetermined short time duration Δt, where 1≦Δt≦30 seconds; and (b) depositing a thin Ge film on top of said treated Si layer, wherein said treatment step of (a) reduces growth time and surface roughness of the thin Ge film (e.g., sub-5 nm or sub-20 nm thick) deposited on the Si layer. In one embodiment, the treatment step (a) is conducted at a steady predetermined temperature T, where 450≦T≦900° C. In one embodiment, the predetermined short time duration Δt is chosen such that less than 10 A of SiGe is deposited.

The present invention also provides for a structure comprising: (a) a treated Si layer formed by treating surface of a strained or relaxed Si layer to gaseous precursors of both Si and Ge for a predetermined short time duration Δt, where 1≦Δt≦30 seconds; and (b) a thin Ge film deposited on top of said treated Si layer, wherein said treating reduces growth time and surface roughness of the thin Ge film deposited on the Si layer.

### BRIEF DESCRIPTION OF THE DRAWINGS

FIG. 1 illustrates the Ge growth process on Si with a SiGe pulse interface treatment as per the teachings of the present invention.

FIG. 2(A) illustrates the SIMS profile of two samples, only one of which is exposed to the SiGe interface pulse of 10 seconds.

FIG. 2(B) illustrates the two resulting structures formed with and without the 10 second SiGe interface pulse.

FIG. 3 is a plot of the Ge film thickness measured by spectroscopic ellipsometry versus Ge film growth time utilizing a no SiGe pulse, and 10 second, and 15 second SiGe pulses.

FIGS. 4(A) and 4(B) depict the 1 μm×1 μm AFM scans of 3.5 nm-thick Ge films grown directly on Si substrates with 15-sec SiGe interface pulse surface treatment, and without SiGe pulse.

FIGS. 5(A) and 5(B) illustrate the 1 μm×1 μm AFM scans of Ge films grown on strained Si substrates without a SiGe pulse surface treatment, and with a 10 second SiGe pulse.

FIG. 6(A) depicts a cross-section transmission electron microscopy (XTEM) image of a strained Si/strained Ge heterostructure on insulator substrate (HOI) substrate.

FIG. 6(B) depicts a schematic diagram of the layer structure described in association with FIG. 6(A).

FIG. 7 illustrates a plot of RMS surface roughness of the Ge film versus various pulse times.

FIG. 8 depicts a plot of the measured effective hole mobility versus inversion charge density for a Ge HOI p-MOSFET, a bulk (90/40) heterostructure p-MOSFET, and the universal Si hole mobility, wherein the Ge HOI was fabricated using the Ge on Si pulse growth method.

FIGS. 9(A), 9(B), and 9(C) illustrates various examples of growing a smooth and thin film of Ge on top of Si.

### DESCRIPTION OF THE PREFERRED EMBODIMENTS

While this invention is illustrated and described in a preferred embodiment, the invention may be produced in many different configurations. There is depicted in the drawings, and will herein be described in detail, a preferred embodiment of the invention, with the understanding that the present disclosure is to be considered as an exemplification of the principles of the invention and the associated functional specifications for its construction and is not intended to limit the invention to the embodiment illustrated. Those skilled in the art will envision many other possible variations within the scope of the present invention.

A method of interface treatment consisting of a short SiGe pulse is utilized to realize the growth of thin (e.g. 10 nm), smooth Ge films on Si. Such Ge films have a number of potential technological applications. For example, incorporating Ge into the channel of a MOSFET is one method to boost device performance and continue the progression to future technology nodes. As the gate length in Si based Metal Oxide Semiconductor Field Effect Transistors (MOSFETs) is scaled to sub-50 nm dimensions, Si carrier mobility and velocity are no longer sufficient to achieve historical performance benchmarks. Ge is an attractive alternative to Si as a channel material because it has intrinsically higher electron and hole mobilities, and carrier velocity.

The ability to grow both a thin and smooth film is essential to realize the performance benefits provided by Ge. A rough Ge film in the channel will compromise the performance enhancement provided by the high mobility material through an increase in carrier scattering, so the surface roughness must be kept to a minimum. Ge is under stress when grown on relaxed or strained Si. Keeping the film thin is desirable when growing Ge on Si because critical thickness constraints limit the thickness to which the Ge film can be grown before the film relaxes via dislocations. A reduction in the growth delay period (“incubation period”) is observed when utilizing the growth method outlined in this invention. Reduced impurity incorporation should be enabled as a result of the reduced growth delay period. In addition, this reduction in the delay period is expected to be beneficial in a manufacturing environment where throughput is a concern.

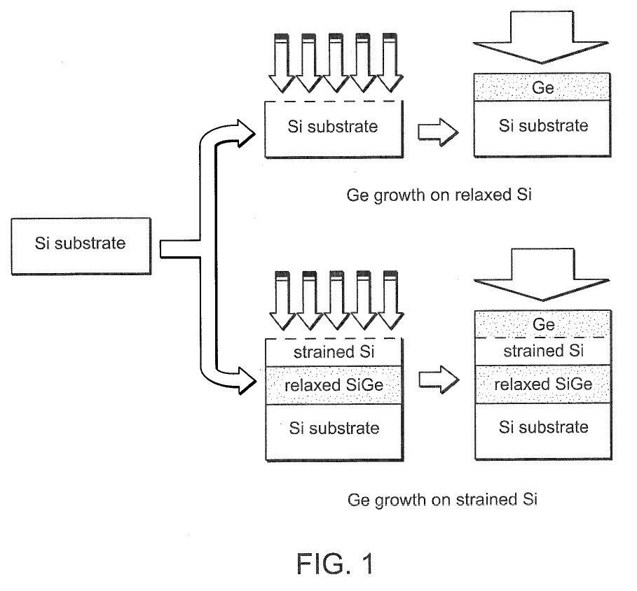

Ge, as a new channel material, has been regarded as one of the main technology enablers for continued progression to future technology nodes. Ge offers the benefit of intrinsically higher electron and hole mobility compared to Si. The higher mobility and carrier velocity increases MOSFET switching speed and current drive. Enabling the growth of thin and smooth Ge on Si allows for the integration of a Ge channel into an existing Si based MOSFET fabrication flow. A depiction of the Ge growth process on Si with a SiGe pulse interface treatment as per the teachings of the present invention is provided in FIG. 1. This method begins by treating the Si surface with a short SiGe “pulse”. This “pulse” consists of exposing the Si surface at an appropriate temperature for a short period (e.g. 525° C. for 10 s) to a mixture of gases containing Si and Ge atoms (which may be silane and germane, for example). After this surface treatment the pure Ge film is deposited. The SiGe pulse interface treatment method is observed to reduce both the total growth time and the surface roughness of thin Ge films grown on Si. This invention applies to the growth of Ge on Si where the Si surface may be a bulk Si substrate, silicon-on-insulator, strained Si, strained Si on insulator, or any other type of substrate with a Si layer on top, upon which the Ge film is grown.

FIG. 1 depicts the Ge on Si growth process with a SiGe pulse surface treatment. Prior to Ge growth on relaxed or strained Si, a SiGe pulse is utilized to promote smooth growth of Ge. This “pulse” consists of exposing the Si surface at an appropriate temperature for a short period (e.g., 525° C. for 10 s) to a mixture of gases containing Si and Ge atoms (which may be silane and germane, for example), prior to growth of the pure Ge film. This SiGe interface pulse treatment applies to the growth of Ge on Si where the Si may be a bulk Si substrate, silicon-on-insulator, strained Si, strained Si on insulator, or any other type of substrate which has a Si layer on top, upon which the Ge film is grown. For the purpose of illustration, the method is shown here as applied to Ge growth on relaxed Si (upper diagram) or strained Si (lower diagram). The resulting Ge film can be quite thin using this method (e.g. 10 nm).

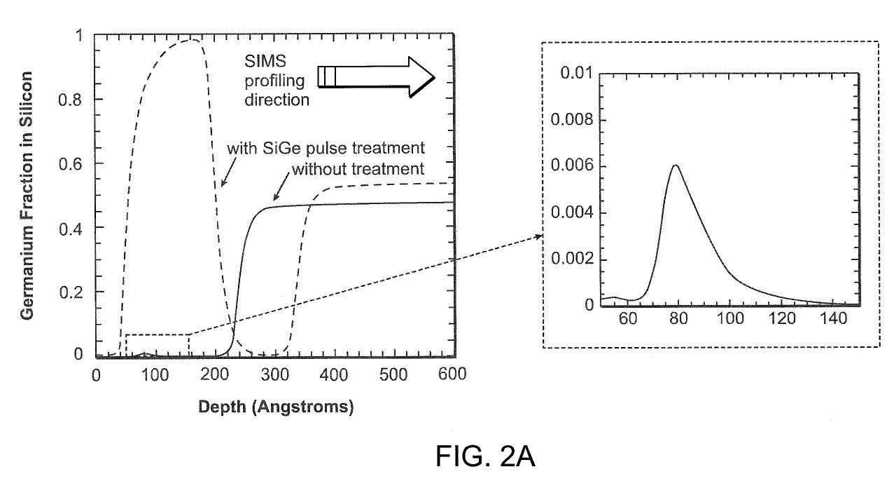

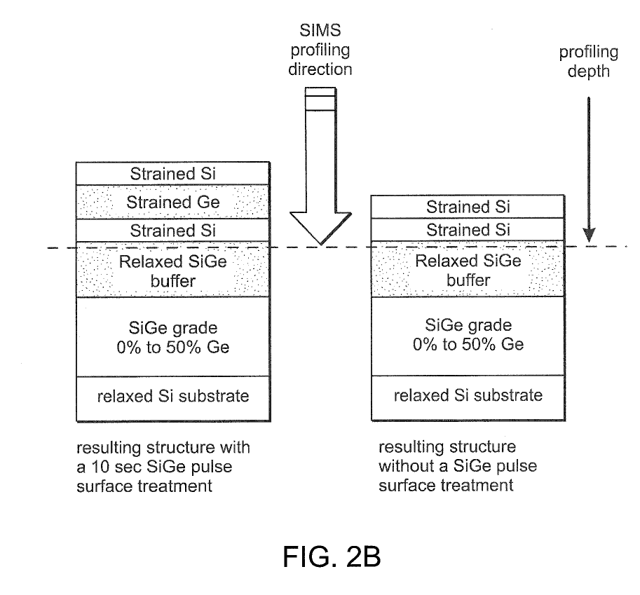

Experiments show that the SiGe pulse reduces the growth delay period (also referred to as the incubation period). This observation was initially made using the data provided in FIG. 2(A) where Secondary Ion Mass Spectrometry (SIMS) provides a profile of the Ge content in two samples depicted in FIG. 2(B). FIG. 2(A) depicts SIMS profiles of two samples where Ge growth was conducted by chemical vapor deposition at a temperature of 365° C. on a Si surface with and without a SiGe interface pulse of 10 seconds. The duration of growth for the sample with the pulse was 170 sec and the duration of Ge growth for the sample without the pulse is 140 seconds. In one sample, Ge growth was attempted on strained Si for 140 seconds without the use of a SiGe pulse. As is evident in the SIMS Ge profile no Ge layer is present in the sample. A small peak in the Ge content is observed between the strained Si films and is magnified in FIG. 2(A). This peak may represent the initial stages of Ge growth on the strained Si film after the growth delay period has passed. When the strained Si surface is treated with a 10 second SiGe pulse, the growth delay is reduced and a Ge growth time of 170 seconds growth results in a 150 Angstrom-thick Ge film. Although there are depth resolution constraints associated with SIMS analysis, it is interesting to note that the 10 sec SiGe pulse is not visible as a separate layer in the SIMS profile, suggesting that the SiGe pulse is very thin.

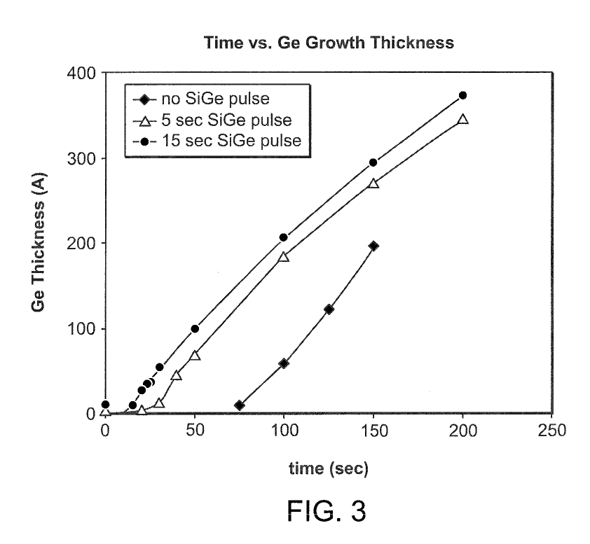

Further experiments were also conducted to document the growth dynamics of Ge on relaxed Si with and without the use of a SiGe interface treatment. FIG. 3 is a plot of the Ge film thickness measured by spectroscopic ellipsometry versus Ge film growth time utilizing a no SiGe pulse, and 10 second, and 15 second SiGe pulses. It reveals a growth delay period (during which little or no Ge film is grown) of about 75 seconds for Ge growth on relaxed Si without the use of a SiGe pulse surface treatment prior to Ge deposition. With the addition of a 15 second SiGe pulse, the growth delay period is reduced from about 75 s to 20 s. The reduction in growth delay improves throughput and improves the reproducibility of the Ge film thickness, which may result from variations in the growth delay period.

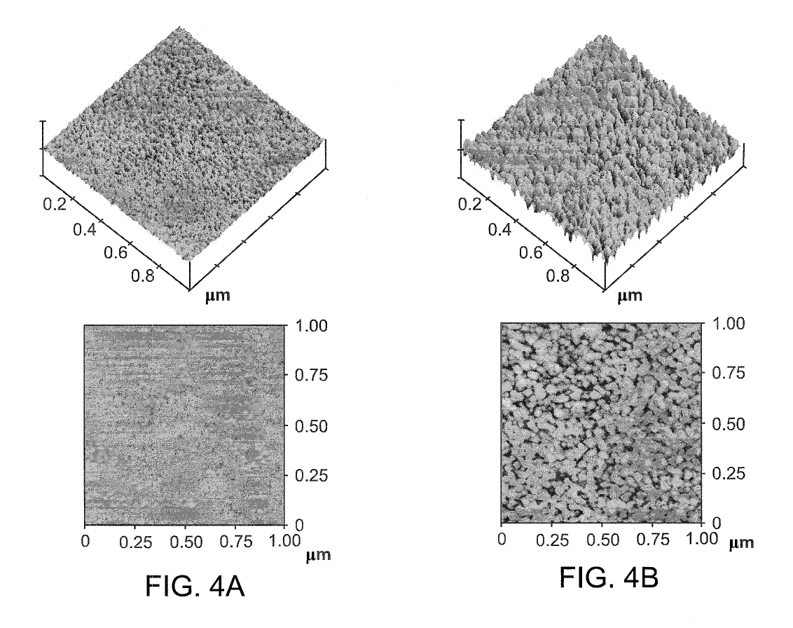

Another advantage of this growth method includes an improvement in the surface roughness of the as-grown Ge film. In a planar MOSFET, architecture surface roughness of the channel material must be kept to a minimum to prevent surface roughness scattering from becoming a significant mobility limiting mechanism. Roughness was measured by conducting Atomic Force Microscopy (AFM). FIGS. 4(A) and 4(B) depict the 1 μm×1 μm AFM scans of 3.5 nm-thick Ge films grown directly on Si substrates with 15-sec SiGe interface pulse surface treatment (see FIG. 4(A)), and without SiGe pulse (see FIG. 4(B)). For FIG. 4(A), RMS roughness is 0.251 nm, with average peak heights of 1.4 nm. FIGS. 4(A) and 4(B) quantify the improvement in surface roughness provided by utilizing the SiGe pulse surface treatment when growing Ge on relaxed Si. The use of a 15 second SiGe pulse prior to Ge growth reduces the RMS surface roughness from 0.686 nm to 0.251 nm for a 3.5 nm-thick Ge film.

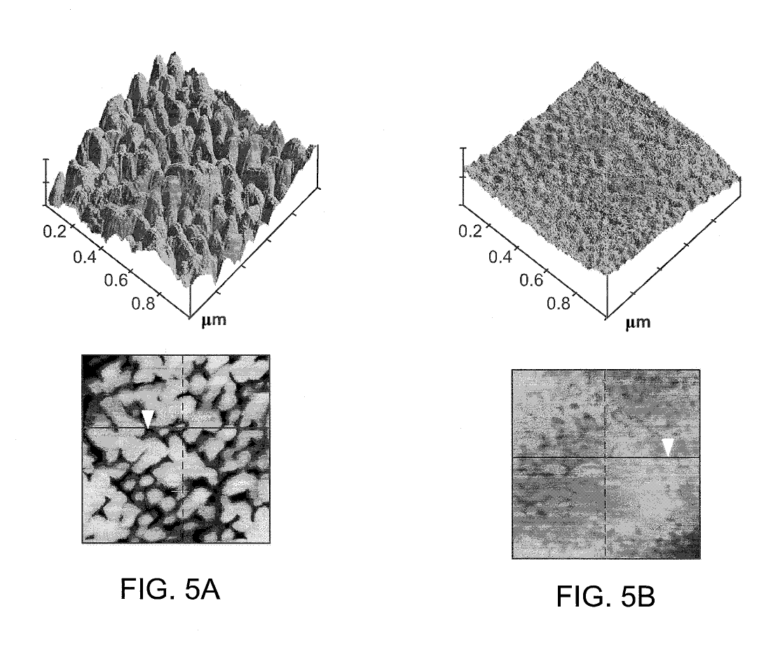

FIGS. 5(A) and 5(B) illustrate the 1 μm×1 μm AFM scans of Ge films grown on strained Si substrates without a SiGe pulse surface treatment (see FIG. 5(A)), and with a 10 second SiGe pulse (see FIG. 5(B)). For FIG. 5(A), RMS is 2.831 nm, with average peak heights of 8 nm. With the surface treatment, the Ge film is much smoother, with RMS value of 0.682 nm and peak heights of 1 nm, as shown in FIG. 5(B). The thickness of the film in FIG. 5(A) is 125 A and the thickness of the film in FIG. 5(B) is 82 A. FIGS. 5(A) and 5(B) quantify the improvement provided with this treatment when conducting Ge growth on strained Si. With the use of a 10 second SiGe pulse prior to Ge deposition the RMS surface roughness is improved from 2.831 nm to 0.682 nm. The improvement in RMS surface roughness on strained Si appears to be less than that of relaxed Si, but the roughness of Ge on strained Si is exaggerated by the cross hatch present on the surface of the strained Si. In the case of strained Si it is better to use the reduction in peak height as an indicator of improvement in surface roughness. On strained Si, with the use of a 10 second SiGe pulse, the peak height is reduced from 8 nm to 1 nm. This is comparable to the peak height reduction from 5 nm to 1.4 nm observed on relaxed Si.

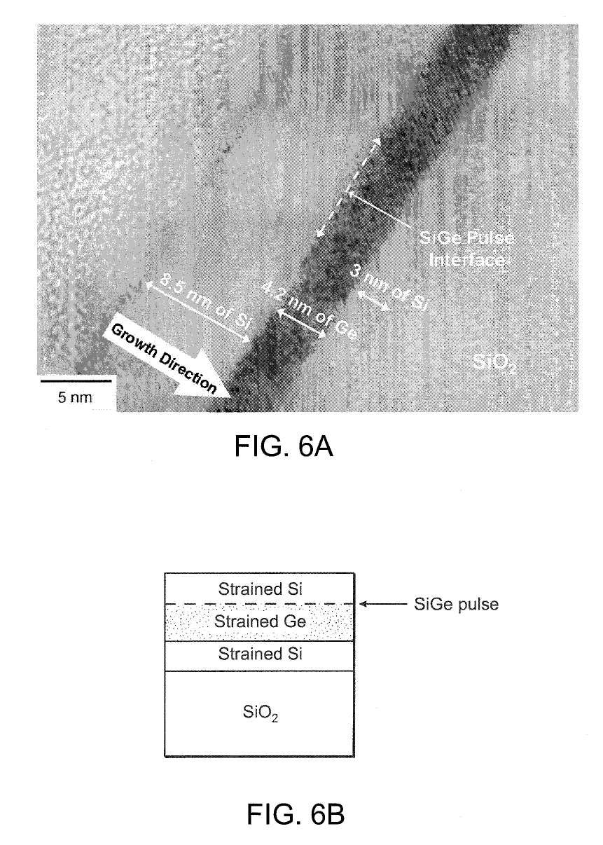

This SiGe pulse interface treatment can be used to grow many device structures of interest. For example, initial application of this method was in the growth of thin Ge films on strained Si for use in fabricating strained Si/strained Ge heterostructures on insulator (HOI). FIG. 6(A) provides a cross-section transmission electron microscopy (XTEM) image of a strained Si/strained Ge herterostructure on insulator substrate (HOI) substrate. The SiGe pulse surface treatment method was utilized to grow the smooth and thin 4.2 nm Ge layer in strained Si, shown in the image. A 10 second SiGe pulse was utilized to grow the smooth Ge layer in the image. As a result of the flip, bond, and etchback technique used in manufacturing this HOI substrate, the Ge film is inverted and the SiGe pulse interface is ultimately located at the top surface of the Ge film, though the pulse took place prior to Ge film growth, as indicated in FIG. 1. A schematic diagram of the layer structure is provided in FIG. 6(B) for a better interpretation of the structure.

The experimental results presented above validate the effectiveness of the SiGe pulse surface treatment used prior to Ge growth. This method reduces both the growth delay period and surface roughness for thin epitaxial Ge films grown on relaxed and strained Si.

The method described uses a SiGe pulse surface treatment prior to epitaxial Ge deposition to realize thin, smooth Ge growth on Si surfaces with a reduced growth delay period. The improved surface roughness ensures that the full performance enhancement potential of Ge can be realized. The SiGe interface pulse is so thin that it does not impact in any measurable way the desired properties of the thin Ge film, such as carrier mobility. The reduction in incubation time improves Ge film thickness reproducibility and throughput, enabling the thickness control required in a manufacturing environment and reducing production cost.

Compared to other methods to produce Ge on Si, this invention is unique in that it enables fabrication of a very thin, smooth Ge layer on Si (for example, 10 nm thick Ge with RMS roughness <0.3 nm CZ Si). Other methods to obtain smooth Ge films rely upon post-growth smoothing techniques (such as chemical mechanical polishing, or wet or gaseous etching, or post-growth annealing, or in-situ annealing). All such methods are more complicated and time consuming than the present invention, and require Ge film treatment which compromises the final thickness control or strain or other desired properties of the Ge film, and are thus not able to produce thin, smooth Ge layers on a Si surface.

The present invention's method can potentially be utilized to incorporate Ge into the channel of Si based MOSFET technology. Ge incorporation into the channel can increase current drive and switching speed through an increase in mobility. MOSFETs are the fundamental component in microprocessors and improving MOSFET performance has the effect of increasing microprocessor speed. The described growth method may also be used in any application where thin, smooth Ge is required on Si.

Potential applications may also exist in the field of optoelectronics. As MOSFETs continue to scale down and approach their scaling limit optical interconnects are becoming an attractive alternative to electrical interconnects. Ge is an attractive material for use in PIN photo-detectors due to its efficient absorption of infrared wavelengths, e.g. 1.3 and 1.55 μm. Such photo-detectors may also require the growth of thin Ge films to serve as the intrinsic absorption region of the device or as the starting layer, to seed thicker Ge grown subsequently on top of the thin, smooth Ge films described in this document.

The present invention provides for a method of growing thin and smooth germanium (Ge) on a strained silicon (Si) layer comprising the steps of: (a) treating surface of the strained Si layer to gaseous precursors of both Si (e.g., silane) and Ge (e.g., germane) for a predetermined short time duration Δt, where 1≦Δt≦30 seconds; and (b) depositing a thin Ge film on top of said treated Si layer, wherein said treatment step of (a) reduces growth time and surface roughness of the thin Ge film (e.g., sub-5 nm or sub-20 nm thick) deposited on the Si layer. In one embodiment, the treatment step (a) is conducted at a steady predetermined temperature T, where 450≦T≦900° C. In one embodiment, the predetermined short time duration Δt is chosen such that less than 10 A of SiGe is deposited.

The present invention provides for a method of growing thin and smooth germanium (Ge) on a relaxed silicon (Si) layer comprising the steps of: (a) treating surface of the relaxed Si layer to gaseous precursors of both Si (e.g., silane) and Ge (e.g., germane) for a predetermined short time duration Δt, where 1≦Δt≦30 seconds; and (b) depositing a thin Ge film on top of said treated Si layer, wherein said treatment step of (a) reduces growth time and surface roughness of the thin Ge film (e.g., sub-5 nm or sub-20 nm thick) deposited on the Si layer. In one embodiment, the treatment step (a) is conducted at a steady predetermined temperature T, where 450≦T≦900° C. In one embodiment, the predetermined short time duration Δt is chosen such that less than 10 A of SiGe is deposited.

The present invention also provides for a structure comprising: (a) a treated Si layer formed by treating the surface of a strained or relaxed Si layer to gaseous precursors of both Si and Ge for a predetermined short time duration Δt, where 1≦Δt≦30 seconds; and (b) a thin Ge film deposited on top of said treated Si layer, wherein said treating reduces growth time and surface roughness of the thin Ge film deposited on the Si layer.

Additional experiments were conducted where Ge was grown on Si with varying pulse durations and the impact of the pulse duration on Ge surface roughness was monitored. This experiment was conducted on bulk Si and Si strained to relaxed Si_{0.5}Ge_{0.5}. The surface roughness was quantified by Atomic Force Microscopy (AFM) measurements. In these experiments it was observed that a 125 Angstrom-thick Ge film grown directly on strained Si without an intermittent SiGe pulse treatment exhibits an RMS roughness of 3.2 nm. Introducing an interfacial 7 second SiGe pulse prior to this deposition reduces the roughness to 0.5 nm. Similarly, an 85 Angstrom Ge film grown on bulk Si without a surface treatment exhibits an RMS roughness of 0.8 nm. When a 5 second SiGe pulse is utilized prior to this Ge growth the RMS roughness is reduced to 0.25 nm.

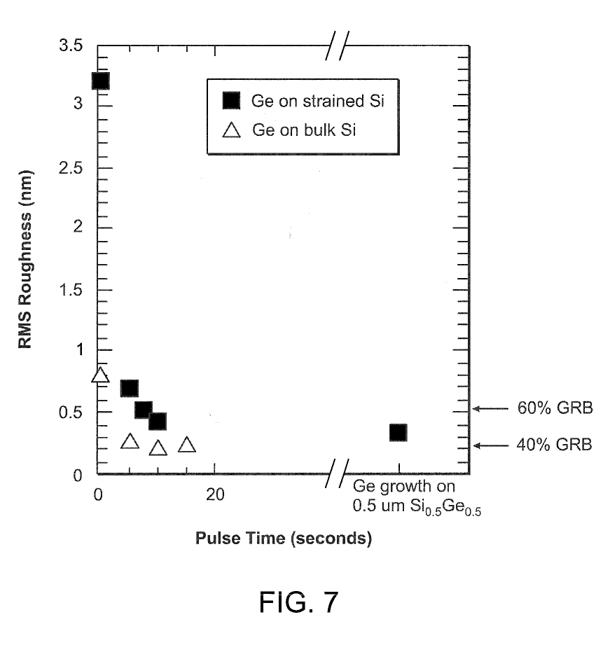

FIG. 7 illustrates a plot of RMS surface roughness of the Ge film versus various pulse times. A trend is observed in these results where the surface roughness decreases as the pulse duration is increased. The roughness of a 125 Angstrom-thick Ge film grown on Si strained to Si_{0.5}Ge_{0.5} is plotted with the solid blue squares. The RMS surface roughness of 90 Angstrom-thick Ge films grown on bulk Si is plotted in the solid red triangles. The RMS roughness is observed to decrease as the pulse time is increased. Reference points are provided for Si_{0.4}Ge_{0.6} (60% GRB) and Si_{0.6}Ge₀₄ (40% GRB) graded buffers.

Minimizing surface roughness is critical to ensure that surface roughness induced scattering doesn't overshadow the performance benefits Ge may provide in the realm of CMOS technology. In a conventional MOSFET carrier, scattering limits the speed with which carriers flow through the device. A figure of merit typically used to quantify this is mobility. If surface roughness in the channel region is significant this performance merit can be severely compromised. The conventional route used to improve MOSFET performance has been to reduce the device dimensions, more specifically the MOSFETs gate length. As device dimensions are reduced parasitic effects begin to degrade device performance and the conventional route of geometric scaling ceases to provide a significant performance enhancement. One option being explored for future CMOS technology nodes is to replace the Si in the channel region with Ge. Ge has intrinsically higher electron and hole mobility making it a potentially better channel material. One possible configuration would be to have a thin, buried, strained Ge channel sandwiched between two thin Si layers. The Ge on Si growth method described in this report would enable such a structure to be easily integrated into an existing Si based device. The smooth nature of the film would ensure that the performance benefits aren't compromised.

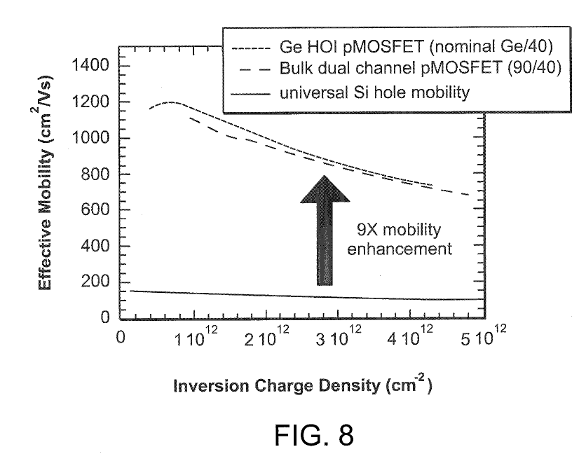

FIG. 8 depicts a plot of the measured effective hole mobility versus inversion charge density for a Ge HOI p-MOSFET, a bulk (90/40) heterostructure p-MOSFET, and the universal Si hole mobility, wherein the Ge HOI was fabricated using the Ge on Si pulse growth method. The Ge HOI substrate consists of a thin 60 Angstrom Ge layer with two thin Si cladding layers. This heterostructure is strained to the lattice parameter of relaxed Si_{0.6}Ge_{0.4}. Also plotted for comparison is the mobility result for a bulk strained-Si/strained-Si_{0.1}Ge_{0.9}/relaxed Si_{0.6}Ge_{0.4} heterostructure. In the bulk heterostructure substrate a Si_{0.1}Ge_{0.9} film is grown directly on a 0.5 μm-thick relaxed Si_{0.6}Ge_{0.4} buffer layer. The strained Si_{0.1}Ge_{0.9} layer in the bulk structure is 60 Angstroms thick. In the mobility plot a 9× mobility enhancement can be observed for both the Ge HOI and bulk heterostructure substrate over the Si universal hole mobility. The high enhancement factor observed in the Ge HOI substrate suggests that the Ge film quality is excellent and that the surface roughness is low enough to prevent surface roughness scattering from degrading the mobility characteristics.

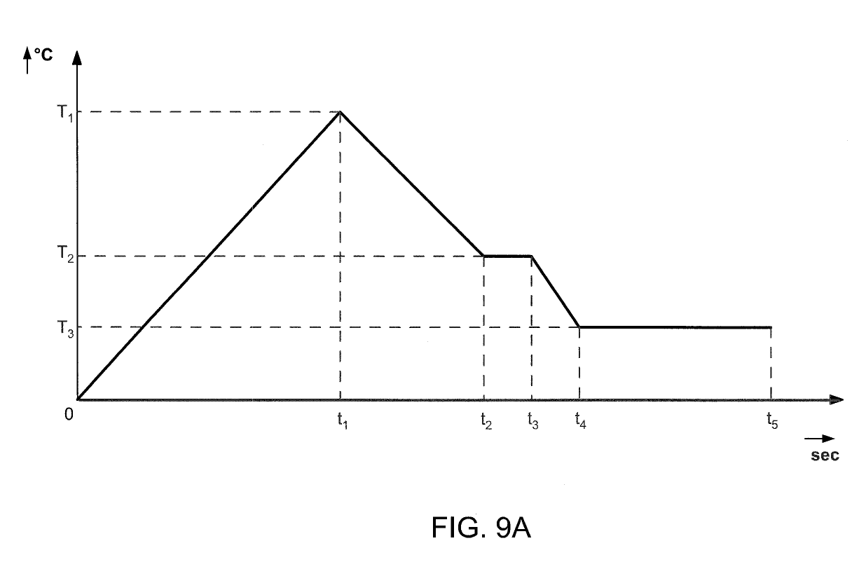

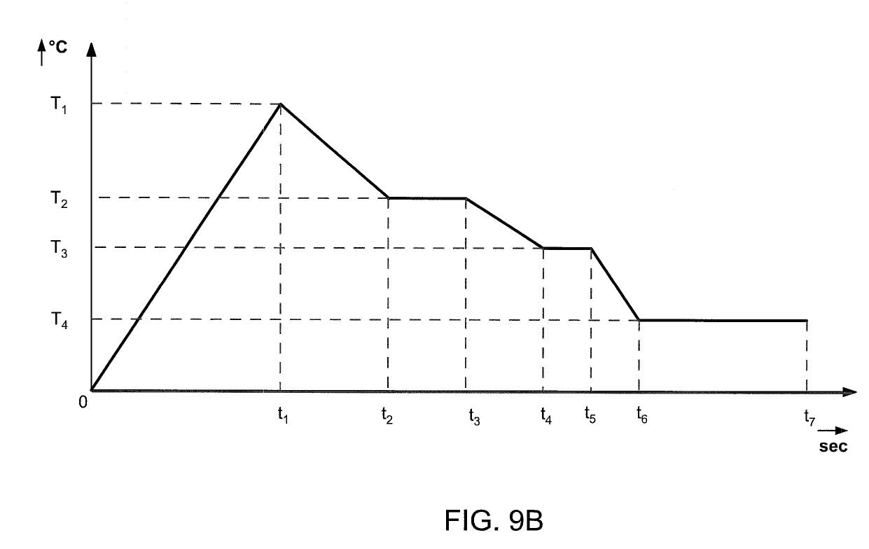

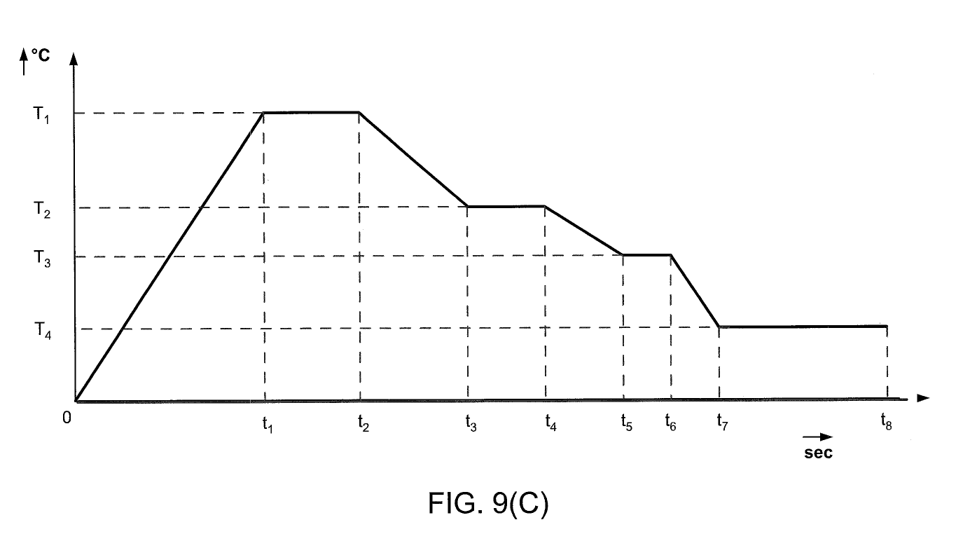

FIG. 9A illustrates an example of the present invention's method as outlined by the steps given below:
(a) heating a Si substrate to a temperature T₁ until time t₁ (in one non-limiting example, temperature T₁ is chosen to be in the range of 700-1000° C. and time t₁ is chosen to be in the range of 0-300 s) in hydrogen (this serves to desorb surface oxides and remove contaminants);
(b) ramping down the substrate temperature to a fixed temperature T₂ (in the preferred embodiment, temperature T₂ is chosen to be in the range of 450-900° C.) until time t₂ (in one non-limiting example, (t₂−t₁) is about 60 s) in hydrogen (it should be noted that no other gases or precursors are used during this temperature ramp step);
(c) holding the substrate temperature fixed at T₂ until time t₃ (in the preferred embodiment, (t₃−t₂) is chosen to be in range of 1-30 s), with hydrogen flowing of the substrate surface, and exposing the Si surface to a mixture of precursors of both Si (such as silane) and Ge (such as germane) for a short duration (e.g. 1 to 30 seconds);
(d) ramping down the substrate temperature to T₃ until time t₄ (in a non-limiting example, temperature T₃ is chosen to be in the range of 335-700° C. and (t₄−t₃) is chosen to be about 60 s) while flowing hydrogen (it should be noted that no other precursors are used in this step); and
(e) growing a thin Ge epitaxial layer on the Si at temperature T₃ until time t₅ (in a non-limiting example, (t₅−t₄) is chosen to be in the range of 10-700 s), using a precursor for Ge (such as germane).

FIG. 9(B) illustrates another example of the present invention's method as outlined by the steps given below:
(a) heating a Si substrate to a temperature T₁ until time t₁ (in one non-limiting example, temperature T₁ is chosen to be in the range of 700-1000° C. and time t₁ is chosen to be in the range of 0-300 s) in hydrogen (this serves to desorb surface oxides and remove contaminants);
(b) ramping down the substrate temperature to a fixed temperature T₂ until time t₂ (in one non-limiting example, temperature T₂ is chosen to be in the range of 600-1000° C. and time (t₂−t₁) is chosen to be about 60 s) in hydrogen (it should be noted that no other gases or precursors are used during this temperature ramp step);
(c) holding the substrate temperature fixed at T₂ until time t₃ (in one non-limiting example, time (t₃−t₂) is chosen to be in the range of 10-300 s), and growing an epitaxial layer of Si using a Si precursor such as silane;
(d) ramping down the substrate temperature to a fixed temperature T₃ (in the preferred embodiment, temperature T₃ is chosen to be in the range of 450-900° C.) until time t₄ (in one non-limiting example, time (t₄−t₃) is chosen to be about 60 s) in hydrogen (it should be noted that no other gases or precursors are used during this temperature ramp step)
(e) holding the substrate temperature fixed at T₃ until time t₅ (in the preferred embodiment, time (t₅−t₄) is chosen to be in the range of 1-30 s), with hydrogen flowing off the substrate surface, and exposing the Si surface to a mixture of precursors of both Si (such as silane) and Ge (such as germane) for a short duration (e.g., 1 to 30 sec.);
(f) ramping down the substrate temperature to T₄ until t₆ (in one non-limiting example, temperature T₄ is chosen to be in range of 335-700° C. and time (t₆−t₅) is chosen to be about 60 s) in flowing hydrogen (no other precursors are used in this step); and
(g) growing a thin Ge epitaxial layer on the Si at temperature T₄ until time t₇, (in one non-limiting example, time (t₇−t₆) is chosen to be in the range of 10-700 s) using a precursor for Ge (such as germane).

FIG. 9(C) illustrates an example of the present invention's method as outlined by the steps given below:
(a) heating a Si substrate to a temperature T₁ until time t₁ (in one non-limiting example, temperature T₁ is chosen to be in the range of 450-900° C. and time t₁ is chosen to be in the range of 0-300 s) in hydrogen (this serves to desorb surface oxides and remove contaminants)
(b) growing a relaxed SiGe layer at temperature T₁ until time t₂ (in one non-limiting example, time (t₂−t₁) is chosen to be about 600 s) by grading the Ge content from x=0 to the final Ge mole fraction, using precursors for Ge and Si such as germane and silane;
(c) ramping down the substrate temperature to a fixed temperature T₂ until time t₃ (in one non-limiting example, temperature T₂ is chosen to be in the range of 600-700° C. and time (t₃−t₂) is chosen to be in the range of 60-120 s) in hydrogen (it should be noted that no other gases or precursors are used during this temperature ramp step);
(d) holding the substrate temperature fixed at T₂ until time t₄ (in one non-limiting example, time (t₄−t₃) is chosen to be about 300 s) and growing an epitaxial layer of strained Si using a Si precursor such as silane, wherein the temperature of growth and thickness are chosen such that the Si layer is strained to the underlying relaxed SiGe layer;
(e) ramping down the substrate temperature to a fixed temperature T₃ (in the preferred embodiment, temperature T₃ is chosen to be in the range of 450-900° C.) until time t₅ (in one non-limiting example, time (t₅−t₄) is chosen to be about 60 s) in hydrogen (it should be noted that no other gases or precursors are used during this temperature ramp step);
(f) holding the substrate temperature fixed at T₃ until t₆ (in the preferred embodiment, time (t₆−t₅) is chosen to be in the range of 1-30 s), with hydrogen flowing off the substrate surface, and expose the Si surface to a mixture of precursors of both Si (such as silane) and Ge (such as germane) for a short duration (e.g. 1 to 30 seconds);
(g) ramping down the substrate temperature to T₄ until time t₇ (in one non-limiting example, temperature T₄ is chosen to be in range of 335-700° C. and time (t₇−t₆) is chosen to be about 60 s) in flowing hydrogen (it should be noted that no other precursors are used in this step); and
(h) growing a thin Ge epitaxial layer on the Si at temperature T₄ until time t₈ (in one non-limiting example, time (t₈−t₇) is chosen to be in the range of 10-700 s), using a precursor for Ge (such as germane).

The methods described above may be employed using chemical vapor deposition in a single-wafer epitaxial growth system, or a batch-type epitaxial growth reactor.

The present invention's method enables the growth of thin and smooth Ge films on Si. The Ge grown may be strained or relaxed. The underlying substrate material may be bulk Si, silicon on insulator, strained Si, strained Si on insulator, etc. One key structure addressed by the present invention's method is the growth of Ge on a Si surface. This method is especially useful for growing thin continuous Ge films of a thickness less than 20 nm on Si or strained Si substrates. Ge films in the sub-20 nm thickness regime grown on strained Si (or sub 5 nm Ge grown on Si) maintain their strain because they are within critical thickness constraints. The present invention's method reduces the growth delay period (“incubation period”) prior to Ge growth that would otherwise occur without use of the SiGe pulse, thereby improving the Ge film quality and allowing for better process control of the Ge film thickness and material properties. The present invention's method dramatically reduces the surface roughness of Ge films grown on a Si substrate, a Si epitaxial layer, or a strained Si layer. The thin smooth Ge films grown using the present invention's method are of high quality and useful for CMOS device applications.

### CONCLUSION

The above described embodiments provide for epitaxially growing thin and smooth Germanium (Ge) on Silicon (Si) utilizing an interfacial Silicon Germanium (SiGe) pulse growth method. While various preferred embodiments have been shown and described, it will be understood that there is no intent to limit the invention by such disclosure, but rather, it is intended to cover all modifications falling within the spirit and scope of the invention, as defined in the appended claims.

1. A method of growing thin and smooth germanium (Ge) on a strained silicon (Si) layer comprising the steps of:
(a) treating surface of the strained Si layer to gaseous precursors of both Si and Ge for a predetermined short time duration Δt, where 1≦Δt≦30 seconds; and
(b) depositing a thin Ge film on top of said treated Si layer, wherein said treatment step of (a) reduces growth time and surface roughness of the thin Ge film deposited on the Si layer.

2. The method of claim 1, wherein said treatment step (a) is conducted at a steady predetermined temperature T, where 450≦T≦900° C.

3. The method of claim 1, wherein said gaseous precursor of Si is silane.

4. The method of claim 1, wherein said gaseous precursor of Ge is germane.

5. The method of claim 1, wherein said method is employed in CMOS device fabrication.

6. The method of claim 1, wherein said method is employed using chemical vapor deposition in a single-wafer epitaxial growth system.

7. The method of claim 1, wherein said method is employed using chemical vapor deposition in a batch-type epitaxial growth reactor.

8. The method of claim 1, wherein said predetermined short time duration Δt is chosen such that less than 10 A of SiGe is deposited.

9. The method of claim 1, wherein said thin Ge film is less than 5 nm thick.

10. The method of claim 1, wherein said thin Ge film is less than 20 nm thick.

11. A method of growing thin and smooth germanium (Ge) on a relaxed silicon (Si) layer comprising the steps of:
(c) treating surface of the relaxed Si layer to gaseous precursors of both Si and Ge for a predetermined short time duration Δt, where 1≦Δt≦30 seconds; and
(d) depositing a thin Ge film on top of said treated Si layer, wherein said treatment step of (a) reduces growth time and surface roughness of the thin Ge film deposited on the Si layer.

12. The method of claim 12, wherein said treatment step (a) is conducted at a steady predetermined temperature T, where 450≦T≦900° C.

13. The method of claim 12, wherein said gaseous precursor of Si is silane.

14. The method of claim 12, wherein said gaseous precursor of Ge is germane.

15. The method of claim 12, wherein said method is employed in CMOS device fabrication.

16. The method of claim 12, wherein said method is employed using chemical vapor deposition in a single-wafer epitaxial growth system.

17. The method of claim 12, wherein said method is employed using chemical vapor deposition in a batch-type epitaxial growth reactor.

18. The method of claim 12, wherein said predetermined short time duration Δt is chosen such that less than 10 A of SiGe is deposited.

19. The method of claim 12, wherein said thin Ge film is less than 5 nm thick.

20. A structure comprising:
(e) a treated Si layer formed by treating surface of a strained or relaxed Si layer to gaseous precursors of both Si and Ge for a predetermined short time duration Δt, where 1≦Δt≦30 seconds; and
(f) a thin Ge film deposited on top of said treated Si layer, wherein said treating reduces growth time and surface roughness of the thin Ge film deposited on the Si layer.
